(19) United States
(12) Patent Application Publication
(10) Pub. No.: US 2013/0292652 A1
(43) Pub. Date: Nov. 7, 2013

(54) DISPLAY DEVICE AND METHOD OF MANUFACTURING THE SAME

(71) Applicant: SAMSUNG DISPLAY CO., LTD., Yongin-si (KR)

(72) Inventor: Jung-Hyun Son, Yongin-si (KR)

(73) Assignee: SAMSUNG DISPLAY CO., LTD., Yongin-si (KR)

(21) Appl. No.: 13/677,050

(22) Filed: Nov. 14, 2012

(30) Foreign Application Priority Data
May 7, 2012 (KR) 10-2012-0048293

(51) Int. Cl. H01L 51/52; H01L 33/56

(52) U.S. Cl. CPC H01L 51/5203; H01L 33/56
USPC 257/40; 257/100; 438/28

(57) ABSTRACT

A display device includes a display panel, a metal encapsulation sheet facing the display panel, a sealing member combining the display panel and the metal encapsulation sheet, and a coating layer covering the metal encapsulation sheet and the sealing member, the coating layer including a silicon-containing resin. A method of manufacturing the display device is also provided.

### CROSS-REFERENCE TO RELATED APPLICATION

This application claims priority to and the benefit of Korean Patent Application No. 10-2012-0048293 filed in the Korean Intellectual Property Office on May 7, 2012, the entire contents of which are incorporated herein by reference.

### BACKGROUND

1. Field

A display device and a method of manufacturing the same are disclosed.

2. Description of the Related Art

Known display devices include liquid crystal displays (LCDs), plasma display panels (PDP), organic light emitting diode display devices (OLED display devices), field effect displays (FED), electrophoretic display devices, and the like.

An OLED display device generally includes a display panel including a thin film transistor, an emission layer or the like, and an encapsulation substrate covering the display panel. The encapsulation substrate may be, for example, a glass plate or a metal sheet. Because the glass plate is fragile to impact from the outside, and is expensive, the metal sheet may be used.

However, the metal sheet may have defects, such as pin holes formed during the process, and oxygen and moisture may be flow in through the defects from outside.

### SUMMARY

Aspects of embodiments of the present invention are directed to a display device having an improved life-span by preventing or reducing the inflow of oxygen and moisture through defects, such as pin holes, in a metal sheet.

In some embodiments, a display device includes a display panel, a metal encapsulation sheet facing the display panel, a sealing member combining the display panel and the metal encapsulation sheet, and a coating layer including a silicon-containing resin, the coating layer covering the metal encapsulation sheet and the sealing member.

The silicon-containing resin may include a polysilsesquioxane, a polysilazane, or a combination thereof. The coating layer may cover an entire surface of the metal encapsulation sheet and an entire side surface of the sealing member.

The metal encapsulation sheet may include a plurality of pin holes, and the plurality of pin holes may be filled with the silicon-containing resin.

The coating layer may have a thickness in a range of about 0.1 μm to about 5 μm.

The display device may also include a barrier film on at least one surface of the metal encapsulation sheet. The barrier film may include polyethylene terephthalate (PET), polycarbonate (PC), polyimide (PI), polypropylene (PP), polyethylene (PE), polyether sulfone (PES), polyethylene naphthalate (PEN), or a combination thereof.

The metal encapsulation sheet may have a thickness in a range of about 1 μm to about 1000 μm. The metal encapsulation sheet may include aluminum (Al), copper (Cu), tungsten (W), an alloy thereof, or a combination thereof.

In some embodiments, an organic layer covers the coating layer.

The display panel includes a base substrate, a pair of electrodes facing each other on the base substrate, and an organic emission layer between the pair of electrodes.

In some embodiments, a method of manufacturing a display device includes combining a display panel and a metal encapsulation sheet by a sealing member, and providing a coating layer covering the metal encapsulation sheet and the sealing member, the coating layer including a silicon-containing resin.

The providing a coating layer may include providing a silicon-containing resin solution to the metal encapsulation sheet and the sealing member and curing the silicon-containing resin solution. The providing a silicon-containing resin solution may include providing the silicon-containing resin by spin coating, screen printing, inkjet printing, one drop filling (ODF), or a combination thereof. The curing a silicon-containing resin solution may be performed by natural curing, heat curing, photo curing, plasma curing, pressing-humidifying curing, or a combination thereof.

The silicon-containing resin solution may include a polysilsesquioxane solution, a polysilazane solution, or a combination thereof.

The method may further include providing a barrier film on at least one surface of the metal encapsulation sheet before combining the display panel with the metal encapsulation sheet by a sealing member. The barrier film may include polyethylene terephthalate (PET), polycarbonate (PC), polyimide (PI), polypropylene (PP), polyethylene (PE), polyethersulfone (PES), polyethylene naphthalate (PEN), or a combination thereof.

The method may further include providing an organic layer covering the coating layer after providing the coating layer.

According to embodiments of the invention, by using a coating layer with a display device, the inflow of oxygen and moisture through defects in the metal encapsulation sheet may be prevented or reduced to improve the life-span characteristics of the display device.

### BRIEF DESCRIPTION OF THE DRAWINGS

FIG. 1 is a schematic cross-sectional diagram of an organic light emitting diode (OLED) display according to one embodiment.

FIG. 2 is a schematic diagram of the filled pin hole of the metal encapsulation sheet according to one embodiment.

FIG. 3 is an enlarged schematic diagram of region “A” of FIG. 1.

FIG. 4 is a schematic cross-sectional diagram of an organic light emitting diode (OLED) display according to another embodiment.

### DETAILED DESCRIPTION

The present invention will be described more fully hereinafter with reference to the accompanying drawings, in which exemplary embodiments of the invention are shown. As those skilled in the art would realize, the described and depicted embodiments may be modified in various different ways, all without departing from the spirit or scope of the present invention.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, the display device according to one embodiment is described. An organic light emitting diode (OLED) display is described as one example of the display device.

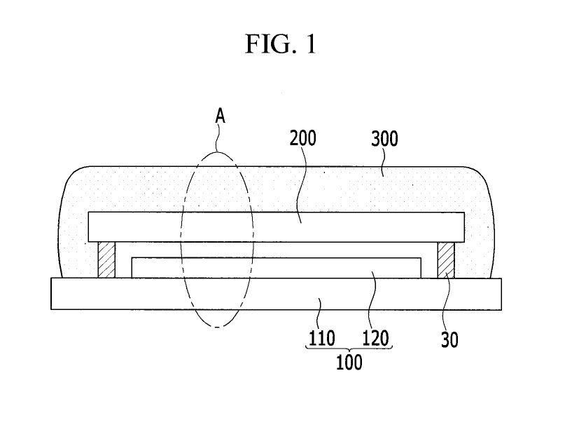

FIG. 1 is a schematic cross-sectional diagram of an organic light emitting diode (OLED) display according to one embodiment.

Referring to FIG. 1, the organic light emitting diode (OLED) display according to one embodiment includes a display panel 100, a metal encapsulation sheet 200, a sealing member 30, and a coating layer 300.

The display panel 100 includes a base substrate 110 and a display part 120.

The base substrate 110 may be a glass substrate, a polymer substrate, or the like.

The display part 120 is disposed on the base substrate 110 and includes a device region formed with an active member such as a thin film transistor (TFT) and a light emitting region formed with an emission layer. The device region and the display region may be disposed separately (e.g., spaced from each other or offset) or may be overlapped. The display part 120 is described hereinafter.

The metal encapsulation sheet 200 is positioned facing the display panel 100, and may be made of, for example, an aluminum (Al)-containing metal such as aluminum (Al) or an aluminum alloy. The metal encapsulation sheet 200 may prevent or reduce the inflow of oxygen and moisture from the outside to protect the display part 120.

The metal encapsulation sheet 200 may be, for example, a single layered aluminum-containing metal sheet or may be prepared by stacking a plurality of aluminum-containing metal sheets. In some embodiments, the metal encapsulation sheet 200 has a thickness in a range of about 1 μm to about 1000 μm. By having a thickness within this range, the sheet may be prevented from deforming from heat during the fabrication process as a result of having excessive thickness, and furthermore, may effectively prevent or reduce the inflow of oxygen and moisture.

The sealing member 30 combines the display panel 100 and the metal encapsulation sheet 200 and may be disposed, for example, at a periphery (e.g., an edge) of the display panel 100. The sealing member 30 may be made of a thermosetting and/or photo curable resin such as an epoxy resin, an acryl-based resin, or the like.

The coating layer 300 covers the metal encapsulation sheet 200, and the sealing member 30, and in some embodiments, may substantially completely cover the entire surface of metal encapsulation sheet 200 and the side surface of sealing member 30. Because the coating layer 300 is formed using a solution as follows, defects, such as pin holes and cracks, in the metal encapsulation sheet 200 may be filled.

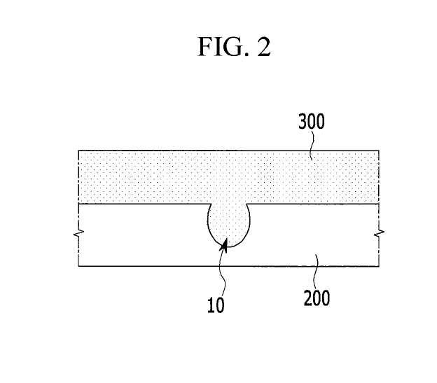

FIG. 2 is a schematic diagram of the filled pin hole of the metal encapsulation sheet according to one embodiment.

Referring to FIG. 2, the metal encapsulation sheet 200 may have a plurality of pin holes 10 that are inevitably produced during the process. The pin hole 10 may provide a passage for oxygen and moisture to enter the device, and the presence of oxygen and moisture may deteriorate the display part 120.

According to one embodiment, a coating layer 300 is provided as a solution on the metal encapsulation sheet 200 having a plurality of pin holes 10 to fill the pin holes 10, thereby closing the passage for oxygen and moisture to enter the device.

Accordingly, the inflow and transfer of oxygen and moisture into the display part 120, through defects such as pin holes in the metal encapsulation sheet 200, may be prevented or reduced to enhance the encapsulation effects on the upper entire surface. In addition, the metal encapsulation sheet 200 may be prevented from being corroded by oxygen and moisture (or the corrosion by oxygen and moisture may be reduced).

Furthermore, the coating layer 300 substantially completely covers the side surface of sealing member 30 as well as the entire surface of metal encapsulation sheet 200, so the inflow of oxygen and moisture through the connection region of between the sealing member 30 and the display panel 100 and between the sealing member 30 and the metal encapsulation sheet 200 may be prevented or reduced to enhance the encapsulation effects on the side surface.

The coating layer 300 may be made of a silicon-containing resin. The silicon-containing resin may include, for example, a polysilsesquioxane, a polysilazane, a derivative thereof, or a combination thereof.

The polysilsesquioxane and/or a derivative thereof may include, for example, polysilsesquioxane having a ladder structure and a side chain of a photo active group, an organic/inorganic hybrid grafted polysilsesquioxane, a polyfluoro-based silsesquioxane, a polysilsesquioxane copolymer, or a combination thereof.

The polysilazane and/or a derivative thereof may include, for example, perhydropolysilazane.

The polysilsesquioxane, polysilazane, and/or a derivative thereof, which are hydrophobic and insulating resins, may effectively prevent a short circuit (or reduce the occurrence of short circuits) which may occur during the module process and driving fabrication process as well as effectively prevent or reduce the inflow of moisture from outside.

In some embodiments, the coating layer 300 has a thickness of about 0.1 to about 5 μm. When the coating layer 300 has a thickness within this range, the coating layer 300 may be uniformly coated on the entire surface of metal encapsulation sheet 200 and the side surface of sealing member 30 and may not crack at the surface of coating layer 300 due to the excessive thickness.

An organic layer (not shown) may be further provided on the coating layer 300 to cover the coating layer 300. The organic layer may be made of, for example, a thermally curable resin composition (e.g., a thermosetting resin) and/or a photocurable resin composition.

The thermally curable resin composition may include a thermally curable resin, a thermal curing agent, a cure accelerating agent, a coupling agent, an antioxidant, and/or a solvent.

The thermally curable resin may include, for example, an epoxy resin. The epoxy resin may include bisphenol-based epoxy, ortho-cresol novolac, multi-functional epoxy, amine-based epoxy, heterocyclic epoxy, substituted epoxy, and naphthol-based epoxy. In some embodiments, the epoxy resin may be bisphenol A epoxy resin, bisphenol F epoxy resin, hydrogenated bisphenol type epoxy resin, alicyclic epoxy resin, aromatic epoxy resin, novolac, dicyclopentadiene type epoxy resin, or a combination thereof. Currently available epoxy resins include a bisphenol-based epoxy resin, an ortho-cresol novolac-based epoxy resin, a multi-functional epoxy resin, an amine based epoxy resin, a heterocyclic epoxy resin, a napthol-based epoxy resin, or the like. Currently available bisphenol-based epoxy resins include EPICLON 830-S, EPICLON EXA-830CRP, EPICLON EXA 850-S, EPICLON EXA-850CRP, and EPICLON EXA-835LV (manufactured by Dainippon Ink & Chemicals Inc.); EPIKOTE 807, EPIKOTE 815, EPIKOTE 825, EPIKOTE827 EPIKOTE 828, EPIKOTE 834, EPIKOTE 1001, EPIKOTE 1004, EPIKOTE 1007, and EPIKOTE 1009 (manufactured by Yuka Shell Epoxy Co.); DER-330, DER-301, and DER-361 (manufactured by DOW Chemical Company); YD-128 and YDF-170 (manufactured by KUKDO CHEMICAL CO. LTD.); and the like. Currently available ortho-cresol novolac-based epoxy resins include YDCN-500-1P, YDCN-500-4P, YDCN-500-5P, YDCN-500-7P, YDCN-500-80P, and YDCN-500-90P (manufactured by KUKDO CHEMICAL CO. LTD.), EOCN-1025, EOCN-1035, EOCN-104S, EOCN-1012, EOCN-1025, and EOCN-1027 (manufactured by Nippon Kayaku Co. Ltd.); and the like. Currently available multi-functional epoxy resins include Epon 1031S (manufactured by Yuka Shell Epoxy Co.); ALALDITE 0163 (manufactured by Ciba Specialty Chemicals Corp.); DENACOL EX-611, DENACOL EX-614, DENACOL EX-614B, DENACOL EX-622, DENACOL EX-512, DENACOL EX-521, DENACOL EX-421, DENACOL EX-411, and DENACOL EX-321 (Nagase ChemteX Corporation); and the like. Currently available amine-based epoxy resins include EPIKOTE 604 (manufactured by Yuka Shell Epoxy Co.); YH-434 (manufactured by Tohto Kasei Co., Ltd); TETRAD-X and TETRAD-C (manufactured by Mitsubishi Gas Chemical Company, Inc.); ELM-120 (manufactured by Sumitomo Chemical Co., Ltd.); and the like. Currently available heterocyclic epoxy resins include PT-810 (manufactured by Ciba Specialty Chemicals Corp.), and the like. Currently available substituted epoxy resins include ERL-4234, ERL-4299, ERL-4221, ERL-4206 (manufactured by Union Carbide Corp.), and the like. Currently available naphthol-based epoxy resins include EPICLON HP-4032, EPICLON HP-4032D, EPICLON HP-4700, EPICLON 4701 (manufactured by Dainippon Ink & Chemicals Inc.), and the like. These may be used singularly or as a mixture of two or more. To obtain good film coating characteristics, a phenoxy resin may be applied, and a high molecular weight resin such as EPIKOTE 1256 (manufactured by Japan Epoxy Resins Co., Ltd.), PKHH (manufactured by InChem Co.), YP-70 (manufactured by Tohto Kasei Co., Ltd), and/or the like.

As the thermal curing agent, any thermal curing epoxy resin commonly used may be used without specific limitation. Examples of the thermal curing agent include a polyamine-based curing agent such as diethylenetriamine, triethylenetetramine, N-aminoethylpiperazine, diamino diphenylmethane, sebacic acid dihydrazide, and/or the like; an acid anhydride curing agent such as phthalic anhydride, phthalic tetrahydroanhydride, phthalic hexahydroanhydride, phthalic methyltetrahydroanhydride, phthalic methylhexahydroanhydride, methyl nadic anhydride, and/or the like; a phenolnovolac curing agent; a polymercaptan curing agent such as trioxanetriethylenemercaptan, and/or the like; a tertiary amine compound such as benzyldimethylamine, 2,4,6-tris(dimethylaminomethyl)phenol, and/or the like; an imidazole compound such as 2-methylimidazole, 2-ethyl-4-methylimidazole, 1-benzyl-2-methylimidazole, and/or the like; and combinations thereof. A solid dispersion type potential curing agent or a potential curing agent encapsulated in a microcapsule, and/or the like may be used.

If an amine-based curing agent is used, an aliphatic amine, a modified aliphatic amine, an aromaticamine, a secondary amine, a tertiary amine, and/or the like may be used. For example, the amine-based curing agent may include benzyldimethylamine, triethanolamine, triethylene tetramine, diethylenetriamine, triethyleneamine, dimethylaminoethanol, tri(dimethylaminomethyl)phenol, and/or the like may be used. The amine-based curing agent may also include various terminal groups such as —OH, —COOH, —SO₃H, —CONH₂, —CONHR (where R represents an alkyl group), —CN(CN)NH₂, —SO₃NH₂, —SO₃NHR (where R represents an alkyl group), and/or —SH. R may be a C1-C10 alkyl group, that is, a C1-C10 linear or branch saturated hydrocarbon group, and in some embodiments, R is a C1-C4 linear or branched alkyl group, and in still other embodiments, R is a methyl group, an ethyl group, an n-propyl group, an isopropyl group, an isobutyl group, an n-butyl group, or a t-butyl group.

If an imidazole-based curing agent is used, it may include imidazole, isoimidazole, 2-methyl imidazole, 2-ethyl-4-methylimidazole, 2,4-dimethylimidazole, butylimidazole, 2-heptadecenyl-4-methylimidazole, 2-methylimidazole, 2-undecenylimidazole,1-vinyl-2-methylimidazole, 2-n-heptadecylimidazole, 2-undecylimidazole, 2-heptadecylimidazole, 2-phenylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl -2-phenylimidazole, 1-guanaminoethyl-2-methylimidazole, an addition product of imidazole and methylimidazole, an addition product of imidazole and trimellitic acid, 2-n-heptadecyl-4-methylimidazole, phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxyl-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethyl-aminophenyl)-4,5-diphenylimidazole, 2-(2-hydroxyphenyl)-4,5-diphenylimidazole, di(4,5-diphenyl-2-imidazole)-benzene-1,4,2-naphthyl-4,5-diphenylimidazole, 1-benzyl-2-methylimidazole, 2-p-methoxystyrylimidazole, and/or the like.

If an acid anhydride curing agent is used, it may include, for example, phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, methylhexahydrophthalic anhydride, methyltetrahydrophthalic anhydride, and/or 5-(2,5-dioxotetrahydrol)-3-methyl-3-cyclohexene-1,2-dicarboxylic acid anhydride.

The cure accelerating agent may include a quaternary ammonium salt, a quaternary sulfonium salt, various metal salts, imidazole, a tertiary amine, and/or the like. Examples of the quaternary ammonium salt include tetra methyl ammonium bromide, tetrabutylammonium bromide, and/or the like. Examples of the quaternary sulfonium salt include tetra phenyl phosphonium bromide, tetrabutylphosphonium bromide, and/or the like. Examples of the metal salt include zinc octylate, tin octylate, and/or the like. Examples of the imidazole include 1-benzyl-2-methyl imidazole, 1-benzyl-2-phenyl imidazole, 2-ethyl-4-methyl imidazole, and/or the like. Examples of the tertiary amine include benzyl dimethyl amine and/or the like.

The boron-based cure accelerating agent may include phenylboronic acid, 4-methylphenylboronic acid, 4-methoxyphenyl boronic acid, 4-trifluoromethoxyphenyl boronic acid, 4-tert-butoxyphenyl boronic acid, 3-fluoro-4-methoxyphenyl boronic acid, pyridine-triphenylborane, 2-ethyl-4-methyl imidazolium tetraphenylborate, 1,8-diazabicyclo[5.4.0]undecene-7-tetraphenylborate, 1,5-diazabicyclo[4.3.0]nonene-5-tetraphenylborate, lithium triphenyl(n-butyl)borate, and/or the like, and/or combinations thereof. The imidazole-based cure accelerating agent may include 2-methylimidazole, 2-undecylimidazole, 2-heptadecylimidazole, 2-ethyl-4-methylimidazole, 2-phenylimidazole, 2-phenyl-4-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecylimidazolium-trimellitate, 1-cyanoethyl-2-phenylimidazolium-trimellitate, 2,4-diamino-6-[2′-methylimidazole-1′]-ethyl-s-triazine, 2,4-diamino-6-[2′-undecylimidazole-1′]-ethyl-s-triazine, 2,4-diamino-6-[2′-ethyl-4′-methylimidazole-1′]-ethyl-s-triazine, 2,4-diamino-6-[2′-methylimidazole-1′]-ethyl-s-triazine isocyanuric acid adduct dihydrate, a 2-phenylimidazole isocyanuric acid adduct, 2-methylimidazole isocyanuric acid adduct dihydrate, 2-phenyl-4,5-dihydroxymethylimidazole, 2-phenyl-4-methyl-5-hydroxymethylimidazole, 2,3-dihydro-1H-pyrrolo[1,2-a]benzimidazole, 4,4′-methylene bis(2-ethyl-5-methylimidazole), 2-methylimidazoline, 2-phenylimidazoline, 2,4-diamino-6-vinyl-1,3,5-triazine, a 2,4-diamino-6-vinyl-1,3,5-triazine isocyanuric acid adduct, a 2,4-diamino-6-methacryloyloxylethyl-1,3,5-triazineisocyanuric acid adduct, 1-(2-cyanoethyl)-2-ethyl-4-methylimidazole, 1-cyanoethyl-2-methylimidazole, 1-(2-cyanoethyl)2-phenyl-4,5-di-(cyanoethoxymethyl)imidazole, 1-acetyl-2-phenylhydrazine, 2-ethyl-4-methylimidazoline, 2-benzyl-4-methyl dimidazoline, 2-ethyl imidazoline, 2-pheny imidazole, 2-phenyl-4,5-dihydroxymethylimidazole, melamine, dicyandiamide, and/or the like, and/or combinations thereof.

The coupling agent may include a silane coupling agent, a titanate-based coupling agent, an aluminate-based coupling agent, a silicon compound, and/or the like, and the coupling agent may be used singularly or as a mixture thereof. The coupling agent may improve adhesion of the resin composition and may decrease viscosity. The coupling agent may be included in a range of about 0.001 to about 5 parts by weight based on 100 parts by weight of the thermally curable resin in the thermally curable resin composition. In some embodiments, the coupling agent may be included in a range of about 0.01 to about 3 parts by weight based on 100 parts by weight of the thermally curable resin in the thermally curable resin composition.

The silane coupling agent functions as an adhesion improving agent for improving adhesion between the surface of inorganic materials such as silica and a resin in the thermally curable resin composition. The silane coupling agent may include an epoxy containing silane, a mercapto containing silane, an amine containing silane, an isocyanate containing silane, and/or the like. The epoxy containing silane may include 2-(3,4 epoxy cyclo hexyl)-ethyltrimethoxysilane, 3-glycidoxytrimethoxysilane, 3-glycidoxypropyltriethoxysilane, 3-glycidoxypropyltriethoxysilane, and/or the like; the amine containing silane may include N-2(aminoethyl)3-aminopropylmethyldimethoxysilane, N-2(aminoethyl)3-aminopropyltrimethoxysilane, N-2(aminoethyl)3-aminopropyltriethoxysilane, 3-aminopropyltrimethoxysilane, 3-aminopropyltriethoxysilane, 3-triethoxysily-N-(1,3-dimethylbutylidene)propylamine, N-phenyl-3-aminopropyltrimethoxysilane, and/or the like; the mercapto containing silane may include 3-mercaptopropylmethyldimethoxysilane, 3-mercaptopropyltriethoxysilane, and/or the like; and the isocyanate containing silane may include 3-isocyanatepropyltriethoxysilane or the like. The silane coupling agent may be used singularly or as a mixture thereof.

The antioxidant may prevent or reduce oxidation degradation during thermal curing of the thermosetting resin composition, thereby further improving the thermal stability of the cured product. The antioxidant may include a phenol based antioxidant, a sulfur based antioxidant, a phosphorous based antioxidant, and/or the like. The phenol based antioxidant may include dibutyl hydroxy toluene, 2,6-di-tetra-butyl-p-cresol (hereinafter, referred to as BHT), and/or the like; the sulfur based antioxidant may include mercapto propionic acid derivative and/or the like; the phosphorous based antioxidant may include triphenylphosphite, 9,10-dihydro-9-oxa-10-phosphaphenanthrene-10-oxide (hereinafter, HCA), and/or the like. The antioxidant may be used singularly or as a mixture thereof. The antioxidant may be included in a range of about 0.001 to about 5 parts by weight based on 100 parts by weight of the thermally curable resin in the thermally curable resin composition, and in some embodiments the antioxidant may be included in a range of about 0.01 to about 0.5 parts by weight based on 100 parts by weight of the thermally curable resin in the thermally curable resin composition.

The photocurable resin composition may include a photocurable resin, a photoinitiator, a coupling agent, a spacer, a photoacid generator, a radical initiator, and/or a solvent.

The photocurable resin may include, for example, an epoxy resin, such as an aromatic epoxy resin, an alicyclic epoxy resin, and/or a mixture thereof. The aromatic epoxy resin may include a biphenyl type, a bisphenol A type, a bisphenol F type, phenol novolac, dicyclopentadiene epoxy resin, and/or the like, and/or a mixture thereof.

The photoinitiator is not specifically limited as long as it photocures the epoxy resin. The photoinitiator may include an aromatic diazonium salt, an aromatic sulfonium salt, an aromatic iodine aluminum salt, an aromatic sulfonium aluminum salt, a metallocene compound, an iron-containing compound, and/or a combination thereof. In some embodiments, an aromatic sulfonium salt may be used, and may include an aromatic sulfonium hexafluoro phosphate compound, an aromatic sulfonium hexafluoro antimonate compound, and/or the like, and or a combination thereof.

As the coupling agent, a silane-based coupling agent, a titanate-based coupling agent, and/or a silicon compound may be used alone or in combination. In some embodiments, a silane coupling agent containing alkoxysilane and diglycidylether in one molecule may be used.

The spacer is not particularly limited as long as it maintains the thickness of a panel after curing. In some embodiments, a spacer capable of maintaining the thickness of a panel in a range of about 5 μm to about 50 μm may be used. In some embodiments, a spacer capable of maintaining the thickness of a panel in a range of about 5 μm to about 25 μm may be used. The spacer may have a spherical shape, a log shape, or the like, however the shape of the spacer is not particularly limited as long as it maintains the thickness of a panel.

The photoacid generator is not particularly limited as long as it produces a Lewis acid or a Bronsted acid by exposure. A sulfide salt based compound such as organic sulfonic acid and/or an onium based compound such as an onium salt may be used. In some embodiments, the photoacid generator may include phthalimidotrifluoromethanesulfonate, dinitrobenzyltosylate, n-decyldisulfone, naphthylimidotrifluoromethanesulfonate, diphenyl iodide, hexafluorophosphate, diphenyl iodide, hexafluoroarsenate, diphenyl iodide, hexafluoroantimonate, diphenylparamethoxyphenylsulfonium triflate, diphenylparatoluenylsulfonium triflate, diphenylparaisobutylphenylsulfonium triflate, triphenylsulfonium hexafluoro arsenate, triphenylsulfonium hexafluoro antimonate, triphenylsulfonium triflate, dibutylnaphthylsulfonium triflate, and/or a mixture thereof.

The radical initiator may be used together with the photoacid generator, and it may include a radical photopolymerization initiator that is decomposed by an electromagnetic energy ray, such as a UV ray, thereby producing a radical, and/or a thermally degradable radical polymerization initiator that is decomposed by heat to produce a radical. The radical photopolymerization initiator may include a type I alpha cleavage initiator such as an acetophenone derivative such as 2-hydroxy-2-methylpropinophenone and/or 1-hydroxycyclohexyl phenyl ketone; an acylphosphine oxide derivative such as bis(2,4,6-trimethylbenzoyl)phenylphosphine oxide; a benzoin ether derivative such as benzoin methyl ether and/or benzoin ethyl ether; and/or the like. Representative examples of commercially available radical photoinitiators include IRGACURE 651, IRGACURE 184, IRGACURE 907, DAROCUR 1173, and IRGACURE 819 (manufactured by Ciba Specialty Chemicals Corp.). A type II photoinitiator may be also used such as benzophenone, isopropylthioxanthone, and/or anthraquinone. Substituted derivatives of the basic compounds described above may also be used.

The thermally decomposable radical polymerization initiator may include peroxides such as 1,1,3,3-tetramethylbutylperoxy-2-ethyl-hexanoate, 1,1-bis(t-butylperoxy)cyclohexane, 1,1-bis(t-butylperoxy)cyclo-dodecane, di-t-butylperoxyisophthalate, t-butylperoxybenzoate, dicumylperoxide, t-butylcumylperoxide, 2,5-dimethyl-2,5-di(t-butylperoxy)hexane, 2,5-dimethyl-2,5-di(t-butylperoxy)-3-hexyne, and/or cumene hydroperoxide. The radical polymerization initiator may be included in an effective amount, for example, in a range of about 0.01 to about 5 parts by weight based on 100 parts by weight of the photocurable resin in the photocurable resin composition.

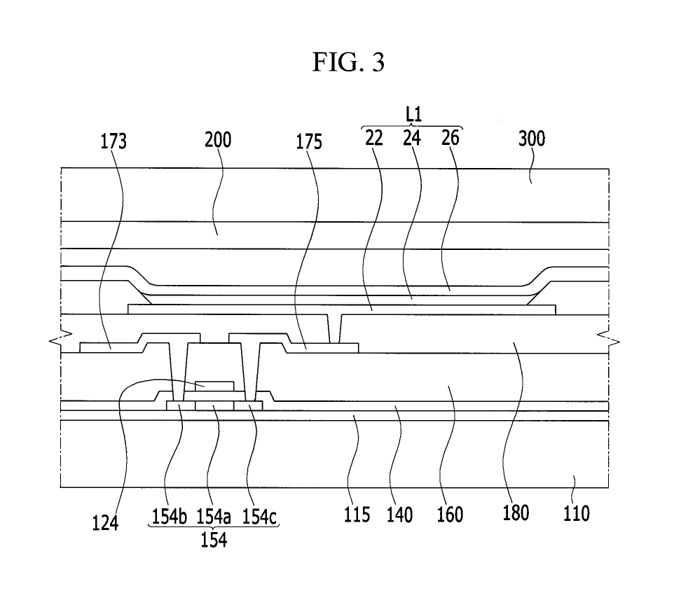

Hereinafter, a display part 120 of the organic light emitting diode (OLED) display is described with reference to FIG. 3 together with FIG. 1.

FIG. 3 is a schematic diagram enlarging “A” region of FIG. 1. Referring to FIG. 3, a buffer layer 115 is disposed on a base substrate 110; a semiconductor layer 154 including a channel region 154a, a source region 154b, and a drain region 154c; a gate insulating layer 140; a gate electrode 124; an interlayer 180; a source electrode 173; a drain electrode 175; and a passivation film 180 are sequentially stacked on the buffer layer 115.

A lower electrode 22, an emission layer 24, and an upper electrode 26 are sequentially stacked on the passivation film 180, forming one light emitting diode L1.

An organic, inorganic, or organic/inorganic filling member may be filled between the display panel 100 and the metal encapsulation sheet 200.

A method of manufacturing the organic light emitting device is described with reference to FIG. 1.

The method of manufacturing an organic light emitting device includes connecting a display panel with a metal encapsulation sheet by a sealing member, and providing a coating layer including a silicon-containing resin covering the metal encapsulation sheet and the sealing member.

The display panel may be connected with the metal encapsulation sheet by a sealing member by applying a sealing member 30 along the periphery (e.g., edge) of display panel 100; placing the metal encapsulation sheet 200 thereon; and curing the sealing member 30 by light and/or heat.

The coating layer 300 may be provided by providing a silicon-containing resin solution to the metal encapsulation sheet 200 and the sealing member 30 and curing the silicon-containing resin solution.

The silicon-containing resin solution may be as described above, and may include, for example, a polysilsesquioxane solution, a polysilazane solution, and/or a combination thereof. The silicon-containing resin solution may further include various kinds of additives including a curing initiator, a coupling agent, and/or a solvent.

The silicon-containing resin solution may be provided by, for example, spin coating, screen printing, inkjet, one drop filling (ODF), and/or a combination thereof.

The silicon-containing resin solution may be cured by, for example, natural curing, heat curing, photo curing, plasma curing, pressing humidifying curing, and/or a combination thereof.

The coating layer 300 may cover the entire surface of metal encapsulation sheet 200 and the side surface of sealing member 30 at the same time by one solution process, thereby preventing or reducing the inflow of oxygen and moisture to the entire surface and side surface of the structure without additional process. Accordingly, the process may be simplified, and the encapsulation effect may be enhanced.

The process may further include providing an organic layer (not shown) on the coating layer 300. In this case, an organic solution may be applied on the coating layer 300 according to at least one method of the above-mentioned methods.

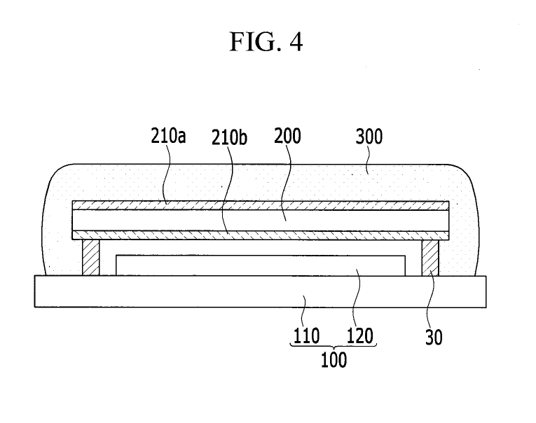

Hereinafter, a display device according to another embodiment is described with reference to FIG. 4.

FIG. 4 is a cross-sectional diagram of an organic light emitting diode (OLED) display according to another embodiment.

Referring to FIG. 4, the organic light emitting diode (OLED) display according to this embodiment includes a display panel 100, a metal encapsulation sheet 200, a sealing member 30, and a coating layer 300 as in the organic light emitting diode (OLED) display according to above embodiment.

However, according to this embodiment, barrier films 210a and 210b are formed on both surfaces of metal encapsulation sheet 200. The barrier films 210a and 210b are exemplarily formed on both surfaces of metal encapsulation sheet 200, but are not limited thereto, and it may be formed on at least one surface of metal encapsulation sheet 200.

The barrier films 210a and 210b may be made of, for example polyethyleneterephthalate (PET), polycarbonate (PC), polyimide (PI), polypropylene (PP), polyethylene (PE), polyether sulfone (PES), polyethylene naphthalate (PEN), or a combination thereof. The barrier films 210a and 210b may have a thickness in a range of about 1 μm to about 1000 μm.

The barrier films 210a and 210b may prevent or reduce the wrinkling and/or bending of metal encapsulation sheet 200 and also prevent or reduce the impact coming from the back side and to prevent or reduce the occurrence of a short circuit.

The organic light emitting diode (OLED) display according to this embodiment may be fabricated by the same method as in the organic light emitting diode (OLED) display according to above embodiment, but it may further include providing a barrier film 210a and 210b on at least one surface of metal encapsulation sheet 200 before connecting the display panel 100 with the metal encapsulation sheet 200 by a sealing member 30.

The barrier films 210a and 210b may be formed by laminating, for example, a polyethylene terephthalate (PET) film on one surface or both surfaces of the metal encapsulation sheet 200 or coating a PET solution on the metal encapsulation sheet 200.

The following examples illustrate the present invention in more detail. These examples, however, are not in any sense to be interpreted as limiting the scope of the present invention.

### EXPERIMENTAL EXAMPLE 1

After preparing an aluminum substrate having pin holes, a perhydropolysilazane solution was coated thereon by spin coating and cured to provide a sample including a coating layer having a thickness of 1.5 μm.

### EXPERIMENTAL EXAMPLE 2

A sample was prepared in accordance with the same procedure as in Experimental Example 1, except that a coating layer having a thickness of 2 μm was provided instead of a coating layer having a thickness1.5 μm.

### COMPARATIVE EXPERIMENTAL EXAMPLE 1

An aluminum substrate having pin hole was prepared.

### Evaluation 1

Samples according to Experimental Examples 1 and 2 and Comparative Experimental Example 1 were measured for moisture transmission. The moisture transmission was measured using AQUATRAN (manufactured by MOCON) according to ASTM F-1249. The results are shown in Table 1.

TABLE 1

| | moisture transmission |
|---|---|
| | g/m² |
| Experimental | 5.1 × 10⁻³ |
| Example 1 | |
| Experimental | 3.2 × 10⁻³ |
| Example 2 | |
| Comparative | 0.8 |
| Experimental | |
| Example 1 | |

Referring to Table 1, the samples according to Experimental Examples 1 and 2 showed the significantly lower moisture transmission than the sample according to Comparative Experimental Example 1. From these results, it was confirmed that the polysilazane coating layer effectively blocked the moisture transmission.

### Manufacture of Organic Light Emitting Diode (OLED) Display

### EXAMPLE 1

An ITO anode was formed on a glass substrate by sputtering and patterned. As an emission layer, 1 wt % of coumarin 6 was doped with Alq3 (tris 8-hydroxyquinoline aluminum) and co-deposited with the anode. Then an Al cathode was deposited thereon to provide an organic light emitting device.

Then a sealing member was applied along with the periphery (e.g., edge) of the glass substrate using a dispenser. An aluminum encapsulation sheet was bonded on the glass substrate by the sealing member, and the sealing member was cured using a solid laser.

Then a perhydropolysilazane solution was coated on the aluminum encapsulation sheet by spin coating to cover the entire aluminum encapsulation sheet and sealing member with the perhydropolysilazane solution.

The coated polysilazane solution was cured at 100° C. for 2 hours to provide a coating layer having a thickness of about 1.5 μm and to provide an organic light emitting diode (OLED) display.

### EXAMPLE 2

An organic light emitting diode (OLED) display was fabricated according to the same procedure as in Example 1, except that the coating layer was formed in a thickness of about 2 μm.

### COMPARATIVE EXAMPLE 1

An organic light emitting diode (OLED) display was fabricated according to the same procedure as in Example 1, except that the coating layer was not formed.

### Evaluation 2

The organic light emitting diode (OLED) displays according to Examples 1 and 2 and Comparative Example 1 were allowed to stand under the atmosphere of a temperature of 85° C. and a humidity of 85% and monitored for the time consumed to generate a spot on the entire surface and the side surface(caused by the inflow of oxygen and/or moisture).

The results are shown in Table 2.

TABLE 2

| | Front view (hr) | Side view (hr) |
|---|---|---|
| Example 1 | 1530 | 1810 |
| Example 2 | 1730 | 1890 |
| Comparative | 640 | 1260 |
| Example 1 | | |

Referring to Table 2, the organic light emitting diode (OLED) displays according to Examples 1 and 2 did not show spots at the front and side surfaces for 1500 hours; on the other hand, the organic light emitting diode (OLED) display according to Comparative Example 1 showed spots at both the front and side surfaces in a significantly shorter time. From the results, it is confirmed that the encapsulation effect was significantly enhanced by providing a coating layer.

The organic light emitting diode (OLED) display is described as one example of the display device, but the present invention is not limited thereto, and the above embodiments may be applied to all display devices applied with the encapsulation substrate.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and equivalents thereof.

What is claimed is:

1. A display device, comprising:
a display panel,
a metal encapsulation sheet facing the display panel,
a sealing member combining the display panel and the metal encapsulation sheet, and
a coating layer comprising a silicon-containing resin, the coating layer covering the metal encapsulation sheet and the sealing member.

2. The display device of claim 1, wherein the silicon-containing resin comprises a polysilsesquioxane, a polysilazane, or a combination thereof.

3. The display device of claim 1, wherein the coating layer covers an entire surface of the metal encapsulation sheet and an entire side surface of the sealing member.

4. The display device of claim 1, wherein the metal encapsulation sheet comprises a plurality of pin holes, and
the plurality of pin holes are filled with the silicon-containing resin.

5. The display device of claim 1, wherein the coating layer has a thickness in a range of about 0.1 μm to about 5 μm.

6. The display device of claim 1, wherein the display device further comprises a barrier film on at least one surface of the metal encapsulation sheet.

7. The display device of claim 6, wherein the barrier film comprises polyethylene terephthalate (PET), polycarbonate (PC), polyimide (PI), polypropylene (PP), polyethylene (PE), polyether sulfone (PES), polyethylene naphthalate (PEN), or a combination thereof.

8. The display device of claim 1, wherein the metal encapsulation sheet has a thickness in a range of about 1 μm to about 1000 μm.

9. The display device of claim 1, wherein the metal encapsulation sheet comprises aluminum (Al), copper (Cu), tungsten (W), an alloy thereof, or a combination thereof.

10. The display device of claim 1, wherein the display device further comprises an organic layer covering the coating layer.

11. The display device of claim 1, wherein the display panel comprises:
a base substrate,
a pair of electrodes facing each other on the base substrate, and
an organic emission layer between the pair of electrode.

12. A method of manufacturing a display device, comprising:
combining a display panel and a metal encapsulation sheet by a sealing member, and
providing a coating layer covering the metal encapsulation sheet and the sealing member, the coating layer comprising a silicon-containing resin.

13. The method of claim 12, wherein the providing a coating layer comprises:
providing a silicon-containing resin solution to the metal encapsulation sheet and the sealing member, and
curing the silicon-containing resin solution.

14. The method of claim 13, wherein the providing a silicon-containing resin solution comprises providing the silicon-containing resin by spin coating, screen printing, inkjet printing, one drop filling (ODF), or a combination thereof.

15. The method of claim 13, wherein the curing a silicon-containing resin solution is performed by natural curing, heat curing, photo curing, plasma curing, pressing-humidifying curing, or a combination thereof.

16. The method of claim 12, wherein the silicon-containing resin solution comprises a polysilsesquioxane solution, a polysilazane solution, or a combination thereof.

17. The method of claim 12, further comprising providing a barrier film on at least one surface of the metal encapsulation sheet before combining the display panel with the metal encapsulation sheet by a sealing member.

18. The method of claim 17, wherein the barrier film comprises polyethylene terephthalate (PET), polycarbonate (PC), polyimide (PI), polypropylene (PP), polyethylene (PE), polyethersulfone (PES), polyethylene naphthalate (PEN), or a combination thereof.

19. The method of claim 12, further comprising providing an organic layer covering the coating layer after providing the coating layer.
